(19) United States
(12) Patent Application Publication
(10) Pub. No.: US 2025/0169074 A1
(43) Pub. Date: May 22, 2025

(54) BCD INTEGRATED CIRCUIT MANUFACTURING METHOD ENABLING LOW-COST EMBEDDED NONVOLATILE MEMORY

(71) Applicant: SEMICONDUCTOR COMPONENTS INDUSTRIES, LLC, Scottsdale, AZ (US)

(72) Inventors: Gang LIU, Camas, WA (US); Santosh MENON, Portland, OR (US)

(73) Assignee: SEMICONDUCTOR COMPONENTS INDUSTRIES, LLC, Scottsdale, AZ (US)

(21) Appl. No.: 18/515,968

(22) Filed: Nov. 21, 2023

(51) Int. Cl. H10B 43/30; H01L 21/28; H01L 21/8249; H01L 27/06; H01L 29/66; H10B 69/00

(52) U.S. Cl. CPC H10B 43/30; H10B 69/00; H10D 30/0413; H10D 64/037; H10D 84/0109; H10D 84/038; H10D 84/401

(57) ABSTRACT

One illustrative integrated circuit manufacturing method includes: a sequence of process operations to provide bipolar devices, CMOS (complementary metal oxide semiconductor) devices, and DMOS (double-diffused metal oxide semiconductor) devices on a monolithic integrated circuit substrate; and further operations to provide nonvolatile memory cells on the monolithic integrated circuit substrate with no additional thermal budget, with no additional implant operations, and with only a single additional mask, relative to the sequence of process operations. The sequence of process operations includes one or more ion implantation operations to form wells and/or buried layers for the bipolar devices, the CMOS devices, and the DMOS devices, on a shared integrated circuit substrate; an annealing operation to heal damage from the one or more ion implantation operations before forming sources and drains for the CMOS and DMOS devices; and gate formation operations to form gates for the CMOS devices and the DMOS devices.

### TECHNICAL FIELD

The present disclosure relates in general to integrated circuit electronics and, more particularly, to a BCD (Bipolar, CMOS, DMOS) integrated circuit manufacturing process that enables embedding of low-cost, high-density SONOS (silicon-oxide-nitride-oxide-semiconductor) nonvolatile memory cells.

### BACKGROUND

The manufacturing process for integrated circuits involves the application of repeated patterning, deposition, and etching steps to a semiconductor wafer or other substrate to form interconnected structures that operate as analog and/or digital components of an electronic circuit. Different process step sequences yield different semiconductor device technologies that may each offer various different advantages.

For example, bipolar junction devices generally offer relatively high speed and low output impedance at the cost of relatively high-power consumption per device. Bipolar junction devices may be desirable for wideband analog circuitry with relatively low complexity, e.g., low noise radio frequency amplifiers.

CMOS (complementary metal-oxide-semiconductor) devices generally offer relatively high input impedance and low power consumption at the cost of relatively nonlinear response curves. CMOS devices may be desirable for digital circuitry with relatively high complexity, e.g., digital processors and control logic.

DMOS (double-diffused metal-oxide-semiconductor) devices generally offer relatively high voltage tolerances at the cost of relatively large area requirements. DMOS devices may be desirable for monitoring and controlling power signals.

The BCD integrated circuit manufacturing process has been developed with a sequence of process steps that enables bipolar junction devices, CMOS devices, and DMOS devices to be formed in isolated regions of a shared semiconductor wafer or substrate and interconnected as needed to form an integrated circuit having all three types of semiconductor devices.

Nonvolatile memory elements are a frequently employed element of many integrated circuit products, enabling information to be retained in a quickly obtainable and compact format even in the absence of power. U.S. Pat. App. Pub. 2017/0345833 (“Method of manufacturing and operating a non-volatile memory cell”), which is hereby incorporated herein by reference in its entirety, provides one example of a BCD process that incorporates nonvolatile memory elements. Unfortunately, this example requires an increased number of masking, implantation, and annealing operations, rendering it undesirably costly and undesirably limiting on the achievable device density.

### SUMMARY

Accordingly, there are disclosed herein illustrative integrated circuit manufacturing methods that may enable embedding of low-cost, high-density nonvolatile memory cells in BCD integrated circuits. One illustrative integrated circuit manufacturing method includes: a sequence of process operations to provide bipolar devices, CMOS (complementary metal oxide semiconductor) devices, and DMOS (double-diffused metal oxide semiconductor) devices on a monolithic integrated circuit substrate; and further operations to provide nonvolatile memory cells on the monolithic integrated circuit substrate with no additional thermal budget, with no additional implant operations, and with only a single additional mask, relative to the sequence of process operations. The sequence of process operations includes one or more ion implantation operations to form wells and/or buried layers for the bipolar devices, the CMOS devices, and the DMOS devices, on the monolithic integrated circuit substrate; an annealing operation to heal damage from the one or more ion implantation operations; and gate formation operations to form gates for the CMOS devices and the DMOS devices.

Another illustrative integrated circuit manufacturing method includes: forming one or more isolation structures to isolate between multiple regions of a semiconductor substrate, the multiple regions including at least one bipolar device region, at least one MOS device region, and at least one nonvolatile memory region; forming a pad oxide layer over the multiple regions; performing ion-implantation of impurities through the pad oxide layer to form at least one well or buried layer in each of the multiple regions; depositing a silicon nitride layer over the pad oxide layer; depositing a sandwich oxide layer over the silicon nitride layer to form an oxide-nitride-oxide stack; heating to anneal away damage from the ion-implantation concurrently with densifying the oxide-nitride-oxide stack; and using a mask to define one or more portions of the oxide-nitride-oxide stack to each serve as a state element in the at least one nonvolatile memory region.

Still another illustrative integrated circuit manufacturing method includes: forming one or more isolation structures configured to isolate between multiple regions of a semiconductor substrate, the multiple regions including at least one bipolar device region, at least one MOS device region, and at least one nonvolatile memory region; performing ion implantation to form one or more wells in each of the at least one bipolar device region and the at least one MOS device region; forming an oxide-nitride-oxide stack in the at least one nonvolatile memory region before annealing away damage from the ion implantation, the annealing serving to densify the oxide-nitride-oxide stack; using a mask to protect one or more portions of the oxide-nitride-oxide stack while removing a remainder portion of the oxide-nitride-stack; forming a gate dielectric layer in place of said remainder portion; and patterning a gate electrode over each of the one or more portions while also patterning a gate electrode at each of one or more MOS device gate locations in each of the at least one MOS device region and the at least one nonvolatile memory region.

Each of the foregoing methods can be employed individually or in conjunction and may include one or more of the following optional features in any suitable combination: 1. the nonvolatile memory cells each include a state transistor having a SONOS (silicon-oxide-nitride-oxide-semiconductor) or MONOS (metal-oxide-nitride-oxide-semiconductor) state element. 2. the nonvolatile memory cells each include an access transistor to enable access to the state element. 3. the further operations include, prior to the annealing operation, forming an oxide-nitride-oxide stack that includes a pad oxide layer used during the one or more ion implantation operations. 4. the further operations include, after the annealing operation, using the single additional mask to retain portions of the oxide-nitride-oxide stack for the state elements and to remove a remainder of the oxide-nitride-oxide stack. 5. as part of using the single additional mask to remove the remainder of the oxide-nitride-oxide stack, the further operations include: performing a reactive ion etch to remove an oxide layer above a nitride layer of the oxide-nitride-oxide stack; and performing a second reactive ion etch to remove the nitride layer. 6. as part of using the single additional mask to remove the remainder of the oxide-nitride-oxide stack, the additional operations further include performing a wet etch to remove the pad oxide layer. 7. the further operations include, after the annealing operation, removing the single additional mask. 8. the further operations include forming a new pad oxide layer after removing the single additional mask. 9. removing the oxide-nitride-oxide stack except for the one or more state elements. 10. providing a gate dielectric layer; and forming a gate over each of the one or more state elements and a gate over the gate dielectric layer at each location of one or more MOS devices. 11. using the gates to form self-aligned sources and drains for the one or more state elements and the one or more MOS devices. 12. creating gate contacts to the gates and surface contacts to the sources and drains and to wells in the at least one bipolar device region, the gate contacts and surface contacts serving as terminals for 2T SONOS memory cells in the at least one nonvolatile memory region, terminals for MOS devices in the at least one MOS device region, and terminals for bipolar devices in the at least one bipolar device region.

### BRIEF DESCRIPTION OF THE DRAWINGS

FIG. 1A is a block diagram of an illustrative BCD integrated circuit.

FIG. 1B is a block diagram of an illustrative nonvolatile memory.

FIG. 2A is a circuit schematic of an illustrative 2T SONOS memory cell.

FIG. 2B is an operations table for the illustrative memory cell of FIG. 2A.

FIG. 3 is a flow diagram of an illustrative integrated circuit manufacturing method.

FIG. 4A is an illustrative cross-section after step 302 of FIG. 3.

FIG. 4B is an illustrative cross-section after step 304 of FIG. 3.

FIG. 4C is an illustrative cross-section after step 306 of FIG. 3.

FIG. 4D is an illustrative cross-section after step 308 of FIG. 3.

FIG. 4E is an illustrative cross-section after step 310 of FIG. 3.

FIG. 4F is an illustrative cross-section after step 318 of FIG. 3.

FIG. 4G is an illustrative cross-section after step 328 of FIG. 3.

FIG. 4H is an illustrative cross-section after step 330 of FIG. 3.

FIG. 4I is an illustrative cross-section after step 332 of FIG. 3.

FIG. 4J is an illustrative cross-section after step 336 of FIG. 3.

FIG. 4K is an illustrative cross-section during step 338 of FIG. 3.

### DETAILED DESCRIPTION

The following description and accompanying drawings are provided for explanatory purposes, not to limit the disclosure. To the contrary, they provide the foundation for one of ordinary skill in the art to understand all modifications, equivalents, and alternatives falling within the scope of the claims.

For simplicity and clarity of illustration, elements in the figures are not necessarily to scale, and the same reference characters in different figures denote the same elements. Additionally, descriptions and details of well-known steps and elements are omitted for simplicity of the description. Although the devices are explained herein as certain n-channel or p-channel devices, or certain n-type or p-type doped regions, a person of ordinary skill in the art will appreciate that complementary devices are also possible in accordance with embodiments of the present invention. It will be appreciated by those skilled in the art that the words during, while, and when as used herein are not exact terms that mean an action takes place instantly upon an initiating action but that there may be some small but reasonable delay, such as a propagation delay, between the reaction that is initiated by the initial action. The use of the words approximately, about, or substantially means that a value of an element has a parameter that is expected to be very close to a stated value or position. However, as is well known in the art there are always minor variances that prevent the values or positions from being exactly as stated. It is well established in the art that variances of up to about ten percent (10%) (and up to twenty percent (20%) for semiconductor doping concentrations) are regarded as reasonable variances from the ideal goal of exactly as described.

Herein, the term “oxide” is shorthand for silicon oxide, or more properly, silicon dioxide. “Nitride” may be used as a shorthand term for silicon nitride, or more properly, trisilicon tetranitride.

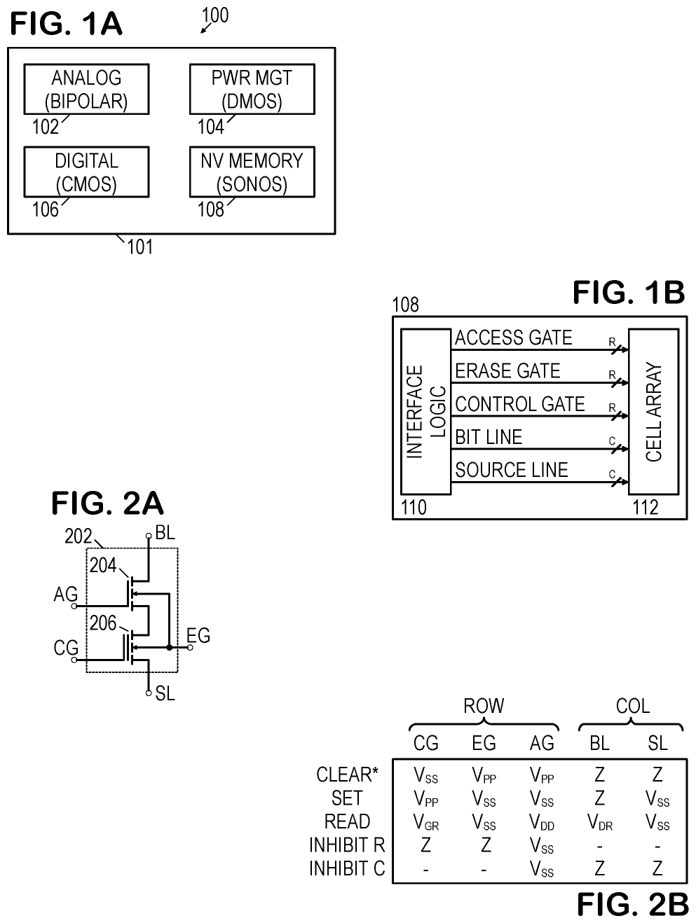

FIG. 1A is a diagram of an illustrative BCD (Bipolar, CMOS, DMOS) integrated circuit 100 having a monolithic semiconductor substrate 101 hosting multiple semiconductor device technologies. The integrated circuit 100 may include analog circuitry 102 implemented using bipolar junction transistors and other bipolar junction devices (e.g., PN diodes, NPN transistors, PNP transistors, silicon controlled rectifiers, JFETs), power management circuitry 104 implemented using DMOS (double-diffused metal oxide semiconductor) devices, digital circuitry 106 implemented using MOS (metal oxide semiconductor) devices (e.g., NMOS, PMOS, CMOS), and nonvolatile memory 108, which may be implemented using a combination of MOS devices and SONOS (silicon-oxide-nitride-oxide semiconductor) or MONOS (metal-oxide-nitride-oxide semiconductor) devices. In the present context, SONOS and MONOS devices are essentially interchangeable and distinguished solely by the composition of the top layer. While the various device types may be isolated from each other with isolation trenches, buried layers, tubs, or other functionally similar isolation structures, they may be interconnected via suitably patterned metal or other conductive layers deposited on the substrate's surface as discussed further below.

FIG. 1B is a block diagram of an illustrative nonvolatile memory 108 having an interface logic circuit 110 that controls various signal lines for a memory cell array 112, enabling the interface logic 110 to write to and read from selected cells in the array 112. The array 112 has bit cells organized in rows and columns. Each row in the array 112 may have an associated Access Gate line, an Erase Gate line, and a Control Gate line. Each column in the array 112 may have an associated bit line and an associated source line.

The array 112 may be implemented using bit cells 202 such as that shown in FIG. 2A. The illustrated bit cell 202 is a two-transistor (2T) SONOS memory cell having an n-channel MOSFET access transistor 204 and an n-channel SONOS state transistor 206. The access gate (AG) line connects to the gate of access transistor 204, and when asserted, establishes a conductive path between the bit line (BL) and the state transistor 206.

The state transistor 206 includes a SONOS or MONOS state element having a floating gate that, depending on its stored charge, provides a high-conductivity or low-conductivity path between the source line (SL) and the access transistor 204. With monitoring of bit line current flow for a given bit line voltage, the interface logic 110 can determine whether the charge on the floating gate represents a binary one or zero.

The control gate (CG) line connects to the gate of the state transistor 206, and the erase gate (EG) line connects to the body terminals of the access transistor 204 and state transistor 206. With suitable control of the control gate and erase gate, the interface logic 110 stores or removes charge from the floating gate.

FIG. 2B is an operations table that may be implemented by the interface logic 110. The operations include Clear, Set, Read, Inhibit Row, and Inhibit Column. For the Clear operation, the interface logic 110 lowers the control gate voltage to V_{SS} (typically zero volts) while raising the erase gate voltage for the selected row to a programming voltage V_{PP}. The programming voltage V_{PP} may be a relatively large voltage sufficient to enable charge tunneling to and from the state transistor's floating gate, e.g., 15 volts. To protect the access transistor, the same programming voltage V_{PP} is applied the access gate, thereby minimizing the access transistor's gate-to-source voltage drop. The bit line and the source line may be left unconnected (in the chart, Z represents a high impedance). Under these circumstances, electrons are drawn away from the floating gate, leaving a net positive charge, which is associated with a more conductive channel during read operations. Note that an asterisk is shown for Clear operation to indicate that this may be a block operation, i.e., one that is applied concurrently to the multiple cells in a given row of the array 112 having a shared erase gate rather than to an individually selectable bit cell.

For the Set operation, the interface logic 110 raises the control gate voltage for the selected row to the programming voltage V_{PP} while lowering the erase gate voltage to V_{SS}. The access gate voltage may also be set to V_{SS} to minimize the access transistor's gate-to-source voltage drop. The bit line of the selected column may be left unconnected while the source line of the selected column may be lowered to V_{SS}. (In the unselected columns, both the bit and source lines are disconnected.) For the selected cell under these circumstances, electrons are drawn to the state transistor's floating gate for the selected bit cells, leaving a net negative charge that is associated with a less conductive channel during read operations.

For the Read operation, the interface logic 110 connects the control gate line for the selected row to an intermediate gate voltage V_{GR} and lowers the erase gate voltage to V_{SS}. The interface logic enables the access transistors by supplying the positive supply voltage V_{DD} (e.g., 3.3 V) to the access gate line. The source line is connected to V_{SS} while the bit line is connected to an intermediate sense voltage V_{DR}. The intermediate gate and sense voltages may be selected to optimize the read operation, e.g., maximizing a ratio between the sense currents associated with the cleared and set states of the state transistor 206. In one example, V_{GR} is about 1.2 V while V_{DR} is 2.5 V.

The interface logic 110 may inhibit operations on unselected rows by disconnecting their control gates and erase gates, and maintaining their access gate lines at V_{SS}. The interface logic 110 may inhibit operations on unselected columns by disconnecting the associated bit lines and source lines.

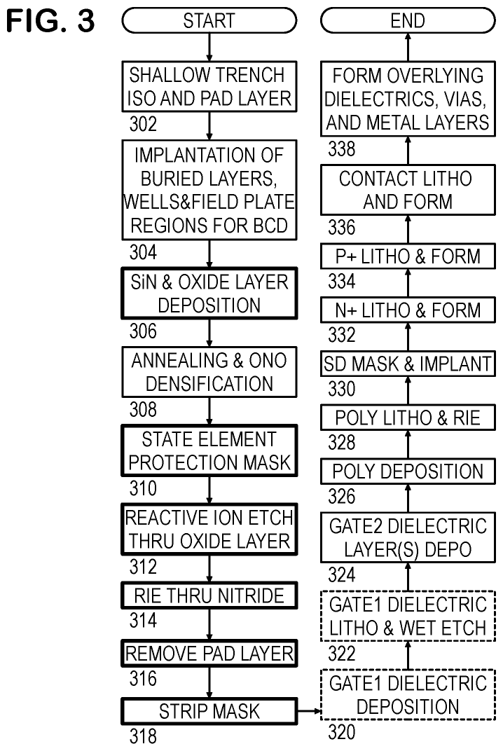

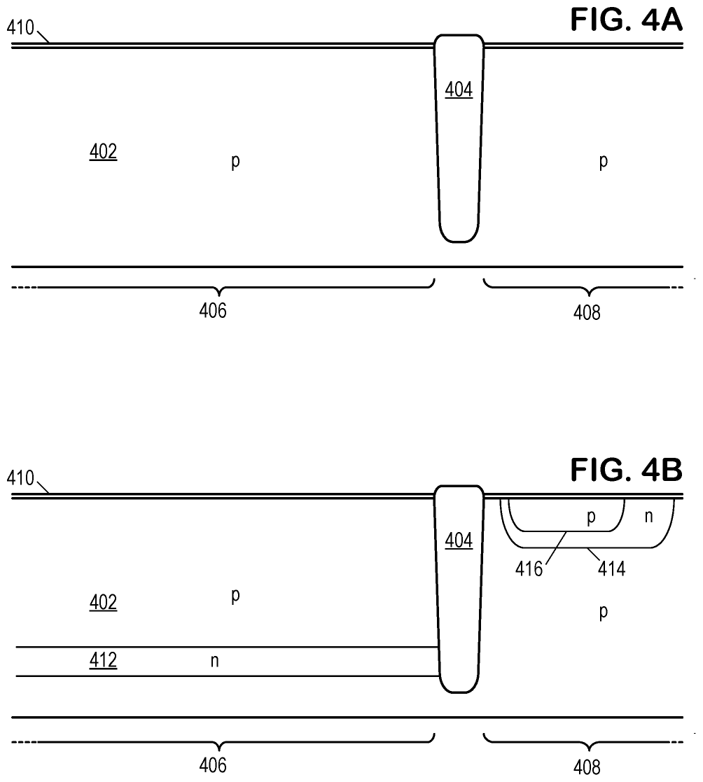

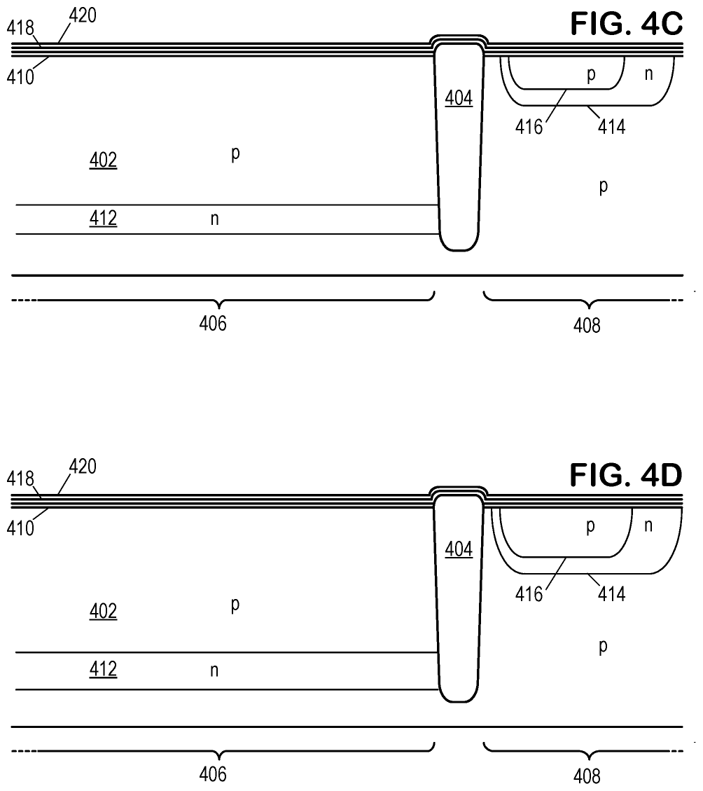

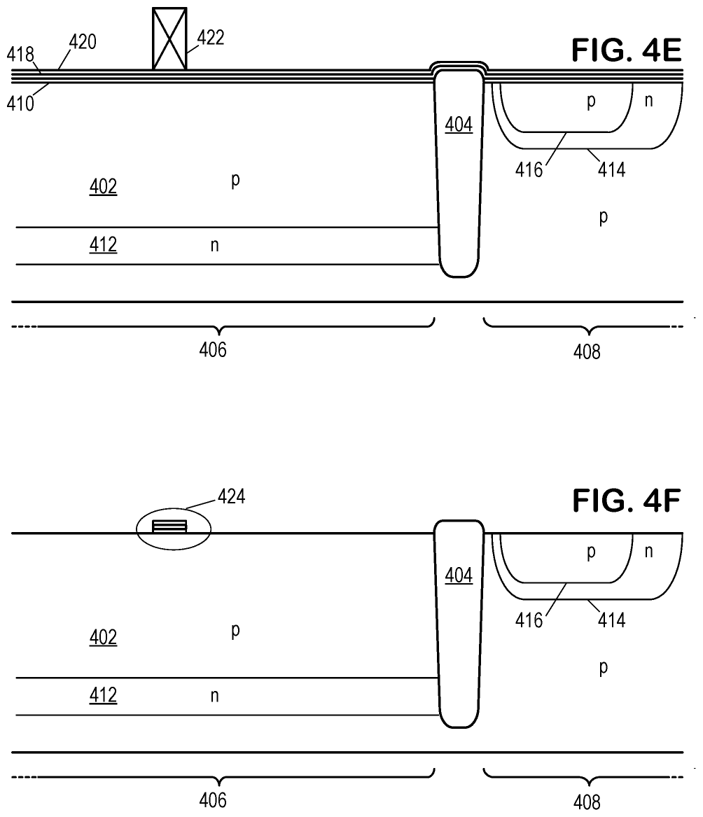

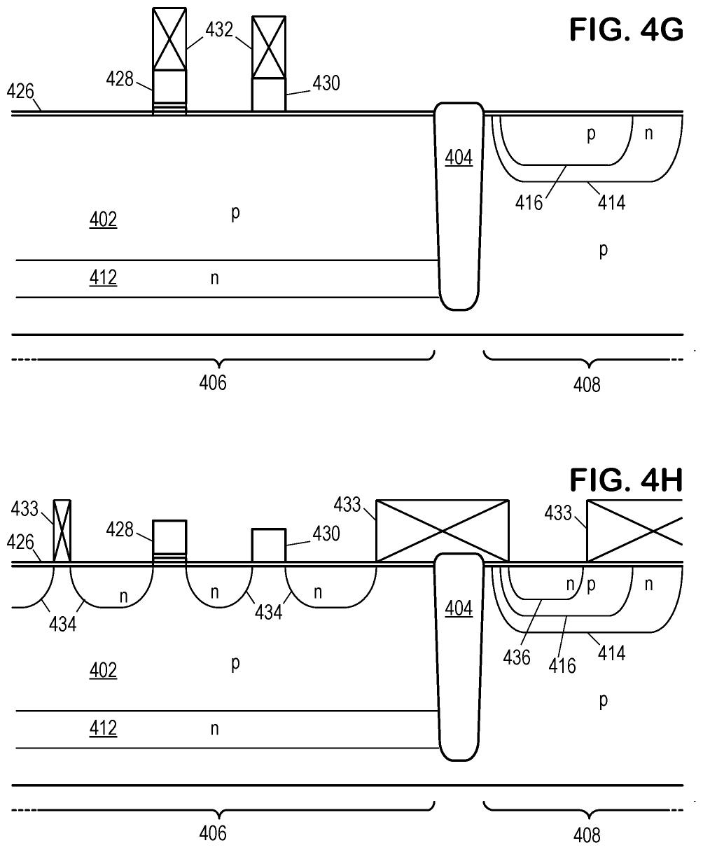

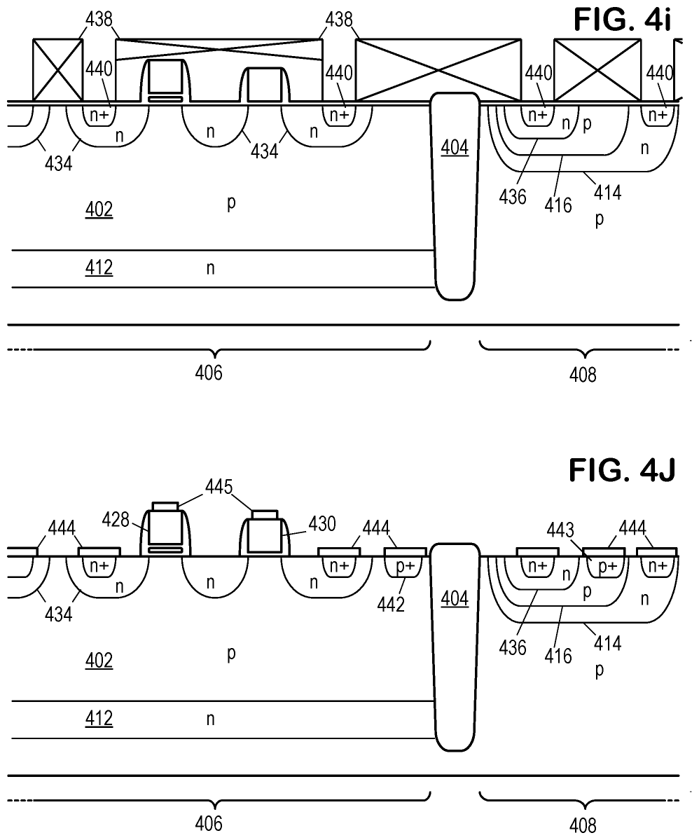

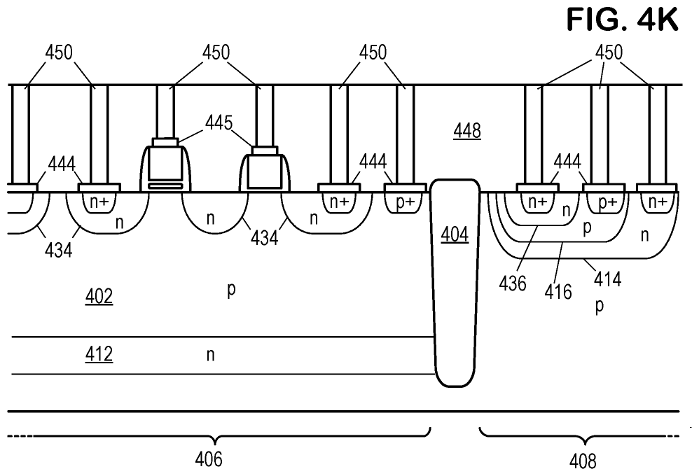

FIG. 3 is a flow diagram showing a sequence of process operations that may be used in an illustrative integrated circuit manufacturing method. As the various blocks are discussed, reference will be made to FIGS. 4A-4K which represent a small portion of the integrated circuit at various steps of the method.

FIG. 3 shows a sequence of process operations 302, 304, 308, and 320-338 to provide bipolar devices, CMOS devices, and DMOS devices on a monolithic integrated circuit substrate. It also shows further operations 306, 310-318 (the blocks with heavy outlining) to provide nonvolatile memory cells on the monolithic integrated circuit substrate with no additional thermal budget and no additional implant operations beyond the existing BCD process represented by blocks 302, 304, 308, and 320-338. Only a single additional mask is employed, and it can be found in block 310. The annealing and implantation operations of the existing operation are sufficient for the new process; thus the incorporation of nonvolatile memory elements can be achieved with no additional thermal budget and no additional implant operations.

The manufacturing method begins in block 302 with the formation of one or more isolation structures, e.g., isolation trenches, between different regions of the semiconductor substrate to provide isolation between the multiple regions. FIG. 4A is an illustrative cross-section after step 302, showing a p-type substrate 402 having a trench 404 separating a memory region 406 from a bipolar region 408. These two regions are representative and in practice there may be multiple such regions and other region types including, e.g., at least one MOS device region for digital circuitry and a DMOS region for power circuitry. The substrate material may be a monocrystalline semiconductor material, a semiconductor-on-insulator substrate, a silicon layer over a glass plate, an epitaxial layer grown on a semiconductor substrate, a semiconductor material comprising a Group 14 element, e.g., carbon, silicon, germanium, or combinations thereof, or another semiconductor material conventionally used in the manufacture of semiconductor components. In accordance with an embodiment, the semiconductor material is lightly doped with an impurity material of p-type conductivity, i.e., a p-type dopant. Alternatively, the semiconductor material may be doped with an impurity material of n-type conductivity.

Trenches may be formed between any adjacent regions to keep them electrically isolated. The isolation trenches 404 may be formed using Shallow Trench Isolation (STI), deep trench isolation, or Local Oxidation of Silicon (LOCOS) techniques.

During or after the trench formation, a thin pad layer 410 is formed on the surface of the semiconductor substrate using, for example, a wet oxidation technique such as an in-situ steam generation (ISSG) operation. Though it may be preferred for the pad layer 410 to be silicon oxide, in practice it can be any suitable dielectric material including, e.g., silicon nitride. In some cases, the pad layer may be supplemented with a stopping layer such as, for example, a polish-stop layer or an etch-stop layer, that are sequentially formed on or from the semiconductor substrate material using a thermal growth technique, a deposition technique, a combination of a thermal growth technique and a deposition technique or the like. The pad layer may be the same material as the stopping layer, or it may be a different material than the stopping layer.

In block 304, a deep ion implantation operation may be performed to create buried layers, wells, and field plates for those regions of the substrate that require such features, e.g., at least one well or buried layer in each of the at least one MOS device region and the nonvolatile memory region. Being able to form wells and buried layers in each of multiple regions is a benefit of the BCD process. Each feature type may be created using a corresponding photoresist layer coupled with a corresponding photolithography operation to pattern the layer, creating a mask with exposed areas that enable the implanted ions to reach only those areas where the features are desired. Thus, the buried layer 412 shown in FIG. 4B may be created using a buried n-layer mask that exposes the memory region 406 and any other areas where a buried n-layer is desired. An n-well mask may be used to create n-well 414 in the bipolar region 408, the power region, and wherever else desired. A p-well mask may be used to create p-well 416 in the bipolar region and wherever else desired. The buried layers, n-wells, and p-wells are doped with impurities (“dopants”), which may be implanted ions, that provide the desired conductivity type. The associated masks are each removed after use.

These deep implantation operations may be followed with an annealing cycle to enable the dopants to integrate with the crystallographic structure of the substrate while also healing dislocations and other crystallographic damage caused during the implantation process. Prior to such annealing, however, the illustrative integrated circuit manufacturing method in block 306 includes the deposition of a silicon nitride layer 418 over the pad oxide layer 410 used during the one or more implantation operations of block 304. Over the silicon nitride layer 418, a second, overlying oxide layer 420 (at times referred to herein as a “sandwich” oxide layer) is deposited to form an oxide-nitride-oxide (ONO) stack that includes a pad oxide layer used during the one or more ion implantation operations. The ONO stack is shown in FIG. 4C. These layers may be deposited across the whole surface of the substrate.

In block 308, the annealing cycle may be performed for the above-given reasons but also to densify the amorphous materials of the oxide-nitride-oxide stack. That is, heating is performed to anneal away damage from the ion-implantation concurrently with densifying the ONO stack. A side effect of the annealing cycle, and a motivation to adhere to a thermal budget, is the migration of dopants, causing an expansion of the doped regions as represented in FIG. 4D.

In block 310, a photoresist layer is added and patterned, creating a protection mask 422 as shown in FIG. 4E to protect, and thereby define, one or more portions of the ONO stack that are to be retained as state elements for the state transistors. Each state transistor has a corresponding portion of the ONO stack to serve as the state element. Mask 422 is the single additional mask referenced elsewhere. It is not a part of the existing BCD process and is the sole additional mask employed by the disclosed process to incorporate nonvolatile memory into the finished circuit. Though only a single state transistor is being shown in the figures, it should be understood that multiple such state transistors may be formed within the nonvolatile memory region 406 and any other nonvolatile memory regions 406. There may be a separate, trench-isolated nonvolatile memory region for each row of the memory cell array 112.

In block 312, a reactive ion etch procedure may be performed using a first set of parameters or “recipe” to remove the exposed portion of the top oxide layer 420, and in block 314 using a second recipe to remove the exposed portion of the nitride layer 418. In block 316, the pad layer 410 may be removed using, e.g., a wet etch. To reiterate, the protection mask 422 is used to retain portions of the ONO stack for the state transistors while removing the remainder of the ONO stack in blocks 312-316. Each of these etch operations may be considered a part of using the single additional mask to remove the remainder of the ONO stack.

In block 318, the mask is removed or “stripped”, leaving an isolated ONO stack that can be used as a SONOS or MONOS state element 424 (FIG. 4F). Thereafter, the BCD process may be performed to complete the integrated circuit, using a standard MOS gate to complete the state transistor. The SONOS configuration is achieved when the standard MOS gate is, e.g., polysilicon. If a metal is used, the state element has a MONOS configuration.

FIG. 3 includes two optional blocks 320, 322, representing operations that may be performed in those situations where it is desired to provide multiple gate thicknesses, e.g., for use with different supply voltages. In block 320, a new pad oxide or other suitable gate dielectric layer is deposited over the exposed silicon surface of the substrate. In block 322, a photolithography operation is performed, i.e., creation of a patterned mask layer with openings to enable removal of the new pad oxide or other suitable dielectric layer wherever thicker gates are not desired. The exposed dielectric layer regions are removed, and the patterned mask layer is stripped before a new oxide or other suitable dielectric layer 426 is deposited in block 324. Thus, the new pad oxide layer 426 can be formed in block 320 and/or block 324 after removing the single additional mask in block 318. The new pad oxide layer(s) 426 may also be referred to as a gate dielectric layer 426.

In block 326, a layer of doped polysilicon (short for polycrystalline silicon) or another suitably conductive gate material is deposited. In block 328, another photolithography operation is performed to pattern a layer of photoresist material, creating openings for removal of the gate material layer where no gates are desired. The removal may be performed using reactive ion etching. Collectively, blocks 320-328 are gate formation operations that, in addition to forming an access gate over the gate dielectric layer for the access transistor and a control gate over the state element for the state transistor for each the memory cells, also serve to form gates 428 over the gate dielectric layer at each location of the MOS devices and DMOS devices. The photolithography operation patterns the layer of photoresist material to serve as a mask for patterning a gate electrode over each of the one or more portions of ONO stack while also patterning a gate electrode at each of the one or more MOS device gate locations in each of the at least one MOS device region and the at least one nonvolatile memory region. FIG. 4G shows a gate electrode 428 for the state transistor and a gate electrode 430 for an access transistor before removal of the overlying photoresist 432.

After the photoresist 432 is stripped, another photolithography operation is performed to create a source-drain mask 433 in block 330, with openings to expose the areas where it is desired to provide transistor sources and drains 434 or other shallow doped regions 436. Ion implantation may be used to create these shallow doped regions. The existing gate structures provide screening of the channel regions, enabling the source and drain regions 434 to be self-aligned as shown in FIG. 4H. Thereafter the mask is stripped and optionally followed by the deposition of a conformal oxide or suitable dielectric layer, e.g., on the order of 20 nm to 500 nm, to insulate the sides of the gate electrodes. If so, an etch or polishing operation may be performed to expose at least a portion of the upper surface of the gate electrodes.

In block 332, another photolithography operation is performed to create an n+ region mask, i.e., a patterned layer 438 exposing those areas where it is desired to provide heavy n-type doping for ohmic contact between an n-type region and a conductive overlayer. An ion implantation operation may be performed to create these n+ ohmic regions 440 as shown in FIG. 4i.

After stripping the patterned layer 438, in block 334, similar operations may be performed to form a p+ region mask and provide heavy p-type doped regions 442 for ohmic contact between a p-type region and a conductive overlayer. In block 336, conductive surface contacts 444 and gate contacts 445 may be formed after a surface-exposing etch using a similar photolithography operation with a refractory metal (e.g., nickel, titanium, platinum, cobalt, tungsten, iridium) or other suitably conductive contact material as shown in FIG. 4J. As shown in FIG. 4J, these surface contacts 444 connect to the sources and drains and to wells in the at least one bipolar device region, while the gate contacts 445 connect to the gates of the state transistors, access transistors, and gates of MOS devices in other regions. The gate contacts and surface contacts provide the connection terminals for 2T SONOS memory cells in the at least one nonvolatile memory region, MOS devices in the at least one MOS device region, and bipolar devices in the at least one bipolar device region.

Thereafter, a thicker oxide or other suitable dielectric layer 448, e.g., on the order of 20 nm to about 500 nm, may be deposited and planarized before the formation and filling of vias 450 providing electrical connection to the surface contacts 444 as shown in FIG. 4K. The via filling may be performed concurrently with the deposition of a first layer of metal or other conductive material, which can be patterned using standard photolithography operations to form connections between the transistors and other devices formed in the substrate.

Additional layers and “metal” layers may be provided in block 338 before the formation of a final passivation layer with apertures for external connections to the integrated circuitry. Standard packaging techniques may be applied such as wire bonding to a lead frame during an encapsulation process, or multi-chip manufacturing in which the chip is bonded to another chip or an interposer that provides additional lead routing.

By now it should be appreciated that nonvolatile memory cells comprised of two active devices have been provided wherein the two active devices include an access transistor and a state transistor. Multiple cells may be grouped together in a row to share a bulk erase gate terminal. In accordance with an embodiment, the access and state transistors may be n-channel devices formed with n-type source and drain regions in a p-type bulk semiconductor substrate. A floating nitride layer is provided between the channel and the gate of the state transistor to trap a positive or negative charge representing a stored bit of information. As explained above, this state element can be provided using only a single additional mask and no increase in thermal budget relative to an existing BCD integrated circuit manufacturing process.

What is claimed is:

1. An integrated circuit manufacturing method that comprises:
a sequence of process operations to provide bipolar devices, CMOS (complementary metal oxide semiconductor) devices, and DMOS (double-diffused metal oxide semiconductor) devices on a monolithic integrated circuit substrate, the sequence of process operations including:
one or more ion implantation operations to form wells and/or buried layers for the bipolar devices, the CMOS devices, and the DMOS devices, on the monolithic integrated circuit substrate;
an annealing operation to heal damage from the one or more ion implantation operations; and
gate formation operations to form gates for the CMOS devices and the DMOS devices; and
further operations to provide nonvolatile memory cells on the monolithic integrated circuit substrate with no additional thermal budget, with no additional implant operations, and with only a single additional mask, relative to the sequence of process operations.

2. The integrated circuit manufacturing method of claim 1, wherein the nonvolatile memory cells each include a SONOS (silicon-oxide-nitride-oxide semiconductor) or MONOS (metal-oxide-nitride-oxide semiconductor) state transistor.

3. The integrated circuit manufacturing method of claim 2, wherein the nonvolatile memory cells each include an access transistor to enable access to the state transistor.

4. The integrated circuit manufacturing method of claim 2, wherein the further operations include, prior to the annealing operation:
forming an oxide-nitride-oxide stack that includes a pad oxide layer used during the one or more ion implantation operations.

5. The integrated circuit manufacturing method of claim 4, wherein the further operations include, after the annealing operation:
using the single additional mask to retain portions of the oxide-nitride-oxide stack for the state transistors and to remove a remainder of the oxide-nitride-oxide stack.

6. The integrated circuit manufacturing method of claim 5, wherein as part of using the single additional mask to remove the remainder of the oxide-nitride-oxide stack, the further operations include:
performing a reactive ion etch to remove an oxide layer above a nitride layer of the oxide-nitride-oxide stack; and
performing a second reactive ion etch to remove the nitride layer.

7. The integrated circuit manufacturing method of claim 6, wherein as part of using the single additional mask to remove the remainder of the oxide-nitride-oxide stack, the further operations include:
performing a wet etch to remove the pad oxide layer.

8. The integrated circuit manufacturing method of claim 5, wherein the further operations include, after the annealing operation:
removing the single additional mask.

9. The integrated circuit manufacturing method of claim 8, wherein the further operations further include forming a new pad oxide layer after removing the single additional mask.

10. An integrated circuit manufacturing method that comprises:
forming one or more isolation structures to isolate between multiple regions of a semiconductor substrate, the multiple regions including at least one bipolar device region, at least one MOS device region, and at least one nonvolatile memory region;
forming a pad oxide layer over the multiple regions;
performing ion-implantation of impurities through the pad oxide layer to form at least one well or buried layer in each of the multiple regions;
depositing a silicon nitride layer over the pad oxide layer;
depositing a sandwich oxide layer over the silicon nitride layer to form an oxide-nitride-oxide stack;
heating to anneal away damage from the ion-implantation concurrently with densifying the oxide-nitride-oxide stack; and
using a mask to define one or more portions of the oxide-nitride-oxide stack to each serve as a state element in the at least one nonvolatile memory region.

11. The integrated circuit manufacturing method of claim 10, further comprising: removing the oxide-nitride-oxide stack except for the one or more state elements.

12. The integrated circuit manufacturing method of claim 11, wherein said removing includes performing a reactive ion etch to remove the sandwich oxide layer.

13. The integrated circuit manufacturing method of claim 12, wherein said removing further includes performing a second reactive ion etch to remove the silicon nitride layer.

14. The integrated circuit manufacturing method of claim 13, wherein said removing further includes performing a wet etch to remove the pad oxide layer.

15. The integrated circuit manufacturing method of claim 11, further comprising:
removing the mask;
providing a gate dielectric layer; and
forming a gate over each of the one or more state elements and a gate over the gate dielectric layer at each location of one or more MOS devices.

16. The integrated circuit manufacturing method of claim 15, further comprising:
using the gates to form self-aligned sources and drains for the one or more state elements and the one or more MOS devices.

17. The integrated circuit manufacturing method of claim 16, further comprising:
creating gate contacts to the gates and surface contacts to the sources and drains and to wells in the at least one bipolar device region, at least some of the gate contacts and surface contacts forming terminals for 2T SONOS memory cells in the at least one nonvolatile memory region, terminals for MOS devices in the at least one MOS device region, and terminals for bipolar devices in the at least one bipolar device region.

18. An integrated circuit manufacturing method that comprises:
forming one or more isolation structures configured to isolate between multiple regions of a semiconductor substrate, the multiple regions including at least one bipolar device region, at least one MOS device region, and at least one nonvolatile memory region;
performing ion implantation to form one or more wells in each of the at least one bipolar device region and the at least one MOS device region;
forming an oxide-nitride-oxide stack in the at least one nonvolatile memory region before annealing away damage from the ion implantation, the annealing serving to densify the oxide-nitride-oxide stack;
using a mask to protect one or more portions of the oxide-nitride-oxide stack while removing a remainder portion of the oxide-nitride-oxide stack;
forming a gate dielectric layer in place of said remainder portion; and
patterning a gate electrode over each of the one or more portions while also patterning a gate electrode at each of one or more MOS device gate locations in each of the at least one MOS device region and the at least one nonvolatile memory region.

19. The integrated circuit manufacturing method of claim 18, further comprising:
using the gate electrodes to form self-aligned sources and drains.

20. The integrated circuit manufacturing method of claim 19, further comprising:
creating gate contacts to the gate electrodes and surface contacts to the sources and drains and to the one or more wells, the gate contacts and surface contacts providing terminals for 2T SONOS cells in the at least one nonvolatile memory region, terminals for MOS devices in the at least one MOS device region, and terminals for bipolar devices in the at least one bipolar device region.
